(19) United States
(12) Patent Application Publication
(10) Pub. No.: US 2016/0352069 A1
(43) Pub. Date: Dec. 1, 2016

(54) SEMICONDUCTOR DEVICE HEADER AND SEMICONDUCTOR DEVICE

(71) Applicant: Shinko Electric Industries Co., LTD., Nagano-ken (JP)

(72) Inventors: Yasuyuki Kimura, Nagano-shi (JP); Takumi Ikeda, Nagano-shi (JP); Masao Kainuma, Nagano-shi (JP); Kazuya Terashima, Nagano-shi (JP)

(73) Assignee: Shinko Electric Industries Co., LTD., Nagano-ken (JP)

(21) Appl. No.: 15/165,335

(22) Filed: May 26, 2016

(30) Foreign Application Priority Data
May 29, 2015 (JP) 2015-110330

(51) Int. Cl. H01S 5/022; H01S 5/024

(52) U.S. Cl. CPC H01S 5/02236; H01S 5/02469

(57) ABSTRACT

A semiconductor device header is provided with a base including a main body and a heat sink. A lead is inserted through a through hole extending through the main body. The is defined by a first opening and a second opening that opens in the upper surface of the main body. The second opening is in communication with the first opening and is smaller than the first opening in a plan view. The first opening is filled with an encapsulant that seals the lead. The second opening is filled with a covering material having a smaller relative permittivity than the encapsulant. The heat sink is located at a position partially overlapped with the first opening in a plan view and separated from the second opening in a plan view.

### CROSS-REFERENCE TO RELATED APPLICATIONS

This application is based upon and claims the benefit of priority from prior Japanese Patent Application No. 2015-110330, filed on May 29, 2015, the entire contents of which are incorporated herein by reference.

### FIELD

This disclosure relates to a semiconductor device header and a semiconductor device that are mainly used for optical communication.

### BACKGROUND

Japanese Laid-Open Patent Publication No. 2004-134697 describes a semiconductor device on which semiconductor elements such as optical elements are mounted. FIG. 8 illustrates a related art example of a semiconductor device 100.

The semiconductor device 100 includes an eyelet 120, signal leads 130, a wiring substrate 140, and a spacer 150. The eyelet 120 includes a main body 121 and a heat sink 122, which projects from the main body 121. Each signal lead 130 is inserted into a through hole 121X, which extends through the main body 121. The spacer 150 is bonded to a mounting surface 122A, which is generally orthogonal to an upper surface 121A of the main body 121. The wiring substrate 140 is bonded to a front surface 150A of the spacer 150. A semiconductor element 160 is mounted on a surface (front surface) of the wiring substrate 140. A conductive pattern 142 formed on the surface of the wiring substrate 140 is electrically connected to the signal leads 130 and the semiconductor element 160. In the semiconductor device 100, the characteristic impedance of the conductive pattern 142 is adjusted to a desired value by adjusting the width, thickness, and the like of the conductive pattern 142 in a suitable manner. This configuration improves the transmission characteristics of high-frequency signals in comparison with a configuration that uses bonding wires, instead of the wiring substrate 140, to connect the signal leads 130, which project upwardly from the through holes 121X, and the semiconductor element 160, which is directly mounted on the heat sink 122.

In the semiconductor device 100, the distance is long between the mounting surface 122A of the heat sink 122 and the signal leads 130. Thus, in the semiconductor device 100, the spacer 150, which is separate from the wiring substrate 140 and the heat sink 122, is arranged between the wiring substrate 140 and the mounting surface 122A to connect the signal leads 130 and the conductive pattern 142 of the wiring substrate 140. However, the spacer 150 increases the number of components and the manufacturing cost of the semiconductor device 100. The heat sink 122 may be overhung above the through holes 121X in order to omit the spacer 150. In this case, however, the heat sink 22 and the through holes 121X cannot be simultaneously formed through stamping. This would increase the manufacturing cost as compared with when manufacturing the eyelet 120 through stamping.

### SUMMARY

One aspect of a wiring substrate is a semiconductor device header provided with a base, a through hole, a lead, an encapsulant, a covering material, and a wiring substrate. The base includes a main body and a heat sink projecting from an upper surface of the main body and formed integrally with the main body. The through hole extends through the main body in a thickness-wise direction. The through hole is defined by a first opening and a second opening. The second opening opens in the upper surface of the main body, and the second opening is in communication with the first opening and is smaller than the first opening in a plan view. The lead is inserted through the through hole. The first opening is filled with the encapsulant to seal the lead. The second opening is filled with the covering material. The covering material has a smaller relative permittivity than the encapsulant. The wiring substrate is bonded to a mounting surface of the heat sink. The wiring substrate includes a conductive pattern, electrically connected to the lead, and a mounting portion, on which a semiconductor element is mounted. The heat sink is located at a position partially overlapped with the first opening in a plan view and separated from the second opening in a plan view.

Other aspects and advantages of the embodiments will become apparent from the following description, taken in conjunction with the accompanying drawings, illustrating by way of example the principles of the invention.

It is to be understood that both the foregoing general description and the following detailed description are exemplary and explanatory and are not restrictive of the invention, as claimed.

### BRIEF DESCRIPTION OF THE DRAWINGS

The embodiments, together with objects and advantages thereof, may best be understood by reference to the following description of the presently preferred embodiments together with the accompanying drawings in which:

FIG. 1 is a schematic perspective view illustrating one embodiment of a semiconductor device header;

FIG. 2A is a schematic cross-sectional view illustrating the semiconductor device header of FIG. 1 and taken along line 2-2 in FIG. 3;

FIG. 2B is a partial, enlarged cross-sectional view of FIG. 2A;

FIG. 3 is a schematic plan view illustrating the semiconductor device header of FIG. 1;

FIG. 4 is a schematic cross-sectional view illustrating the semiconductor device header of FIG. 1 and taken along line 4-4 in FIG. 3;

FIG. 5 is a schematic cross-sectional view illustrating a semiconductor device including the semiconductor device header of FIG. 1;

FIG. 6 is a graph illustrating the reflective characteristics of the semiconductor device header of FIG. 1;

FIG. 7 is a schematic perspective view illustrating a modified example of a semiconductor device; and

FIG. 8 is a schematic cross-sectional view illustrating a related art semiconductor device.

### DESCRIPTION OF THE EMBODIMENTS

One embodiment will now be described with reference to the drawings. In the drawings, elements are illustrated for simplicity and clarity and have not necessarily been drawn to scale. To facilitate understanding of the cross-sectional structure of each member, hatching lines may not be illustrated or be replaced by shadings in the cross-sectional drawings.

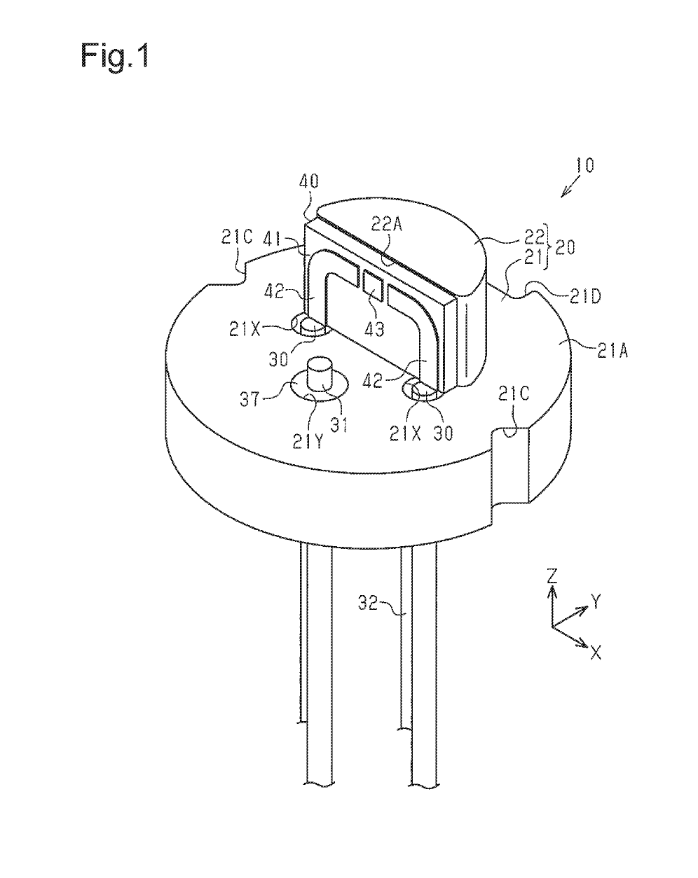

As illustrated in FIG. 1, a semiconductor device header 10 (hereafter referred to as the header 10) includes an eyelet 20 serving as a base, signal leads 30, a monitor lead 31, a ground lead 32, and a wiring substrate 40. The signal leads 30, the monitor lead 31, and the ground lead 32 may be formed from a ferrous alloy such as Kovar or 52 Alloy.

The eyelet 20 includes a main body 21 and a heat sink 22, which includes a mounting surface 22A. A wiring substrate 40 is mounted on the mounting surface 22A. The main body 21 and the heat sink 22 are formed integrally with each other. The main body 21 and the heat sink 22 functions as a heat dissipation plate that dissipates heat from the semiconductor elements mounted on the header 10. It is thus preferred that the main body 21 and the heat sink 22 be formed from a metal having good thermal conductivity. Further, it is preferred that the wiring substrate 40 mounted on the mounting surface 22A and the semiconductor elements mounted on the wiring substrate 40 be formed from materials having thermal expansion coefficients that are about the same. In this manner, for example, iron may be used as the material of the main body 21 and the heat sink 22. Plating may be applied to the surfaces of the main body 21 and the heat sink 22.

The main body 21 is, for example, disk-shaped. The main body 21 may have a diameter of, for example, approximately 5.6 to 9.0 mm. Further, the main body 21 may have a thickness of, for example, approximately 1.0 to 2.0 mm. In this specification, the term “disk-shaped” refers to a form having a generally circular planar shape and a given thickness. The term “disk-shaped” does not limit a ratio of the thickness relative to the diameter to a specific ratio. The term “disk-shaped” also covers a form that partially includes a recess or a projection.

The rim of the main body 21 includes two notches 21C that are recessed from the outer circumference toward the center of the main body 21. The notches 21C may be used to position a semiconductor element mounting surface when mounting semiconductor elements on the header 10 (wiring substrate 40). The two notches 21C are, for example, arranged opposing each other. Each notch 21c has, for example, a V-shaped planar shape.

In this specification, the term “plan view” refers to the view of a subject in a direction that is normal to the upper surface 21A of the main body 21. The term “planar shape” refers to the shape of a subject as viewed in the normal direction of the upper surface 21A of the main body 21. Hereinafter, the direction normal to the upper surface 21A of the main body 21 is referred to as the Z-direction, the direction normal to the mounting surface 22A is referred to as the Y-direction, and the direction perpendicular to both Z and Y-directions is referred to as the X-direction. For the sake of brevity, the side of the eyelet 20 where the heat sink 22 is located is referred to as the upper side, and the side of the eyelet 20 opposite to the heat sink 22 is referred to as the lower side. Nevertheless, the semiconductor device header 10 may be used upside down and be arranged at any angle.

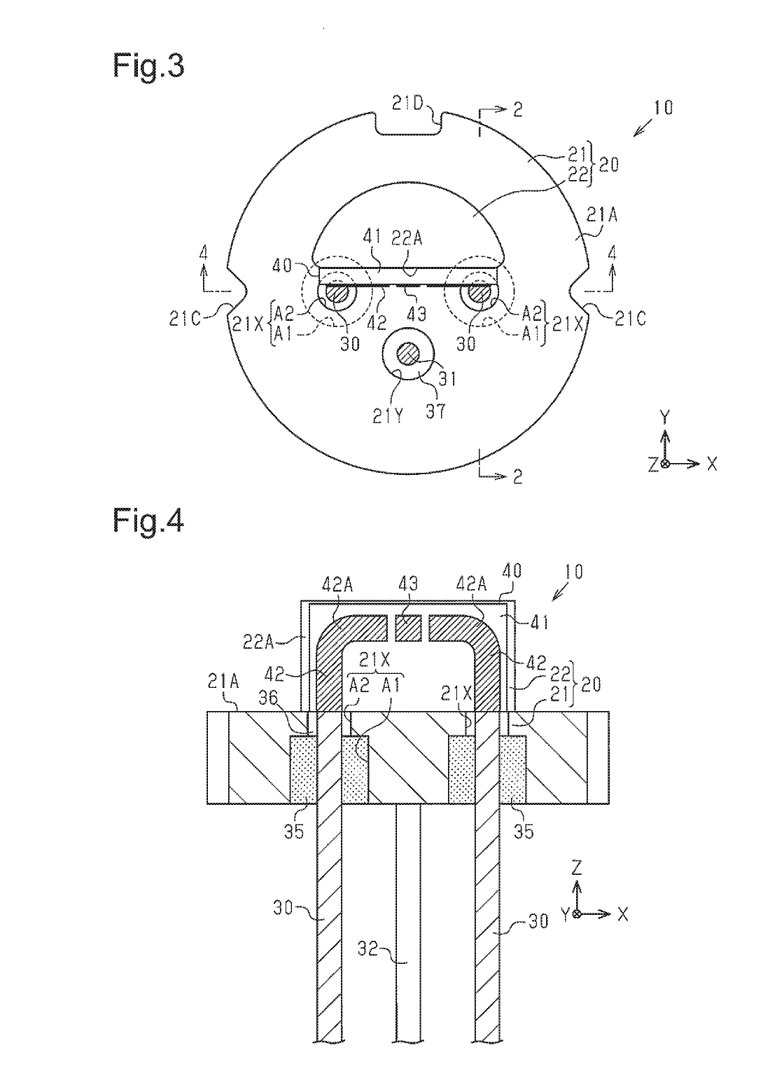

In addition to the notches 21C, the rim of the main body 21 includes a notch 21D that is recessed from the outer circumference toward the center of the main body 21 in a plan view. The notch 21D may be used to position the header 10 in a rotation direction. The notch 21D has a planar shape that is, for example, generally U-shaped (refer to FIG. 3). The notches 21C and 21D may be omitted when they are not necessary.

The main body 21 may include through holes 21X at given locations (two locations). The through holes 21X extend through the main body 21 in the thickness-wise direction (Z-direction). The two through holes 21X are arranged in the X-direction and spaced from each other by a given distance.

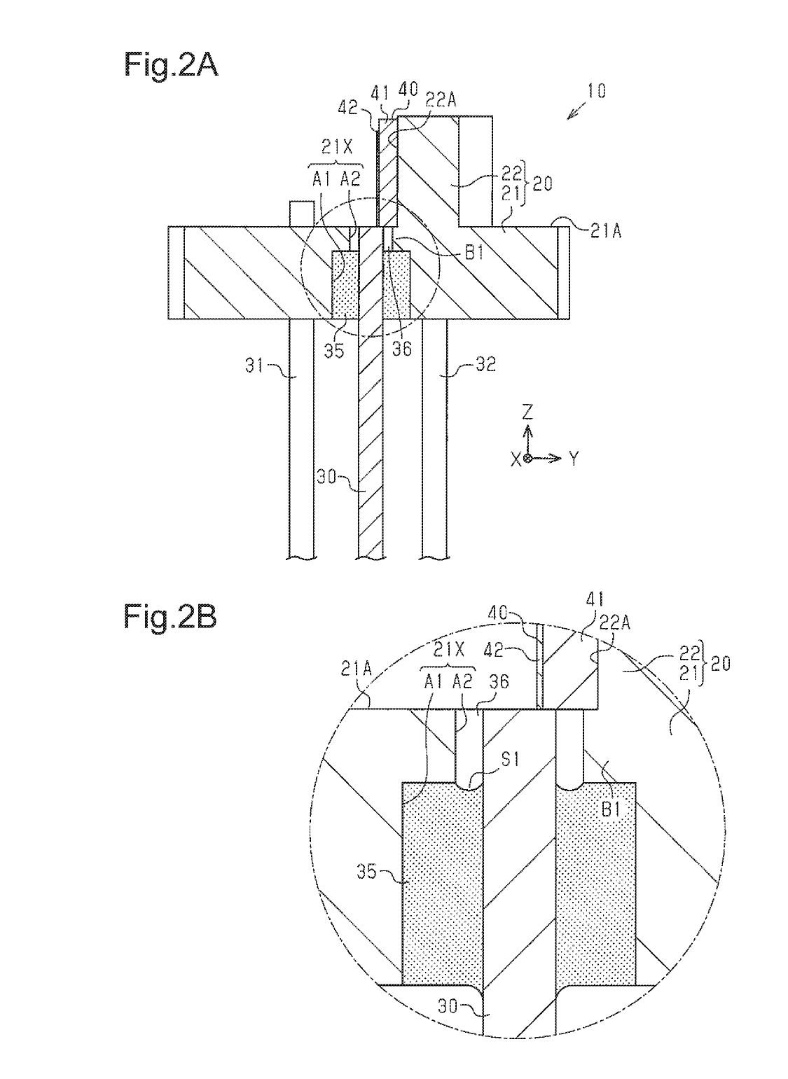

As illustrated in FIG. 2A, each through hole 21X extends through the main body 21 from the upper surface 21A to the lower surface. Each through hole 21X is defined by an opening A1 and an opening A2, which opens in the upper surface 21A of the main body 21 and is in communication with the opening A1. The opening A2 is smaller than the opening A1 in a plan view. The openings A1 and A2 are, for example, cylindrical, and the opening A2 has a smaller diameter than the opening A1. The opening A2 is located at a position that is overlapped with the opening A1 in a plan view. Further, the openings A1 and A2 are concentric. In the present example, as illustrated in FIG. 2B, the main body 21 includes a projection B1 that is located above each opening A1 and projected into the through hole 21X from an upper outer rim of each opening A1 to define the opening A2. In other words, the projection B1 is ring-shaped and located at a position overlapping the circumferential region of the opening A1, and the inner region surrounded by the projection B1 defines the opening A2. Consequently, a step is formed in the through hole 21X by the inner surface of the projection B1 defining the opening A2, the bottom surface of the projection B1, and the inner surface of the main body 21 defining the opening A1.

As illustrated in FIG. 2A, each signal lead 30 is, for example, cylindrical. The signal lead 30 has a diameter of, for example, 0.15 to 0.6 mm. The signal lead 30 is inserted through the corresponding through hole 21X. Accordingly, the axial direction of the signal lead 30 coincides with the thickness-wise direction (Z-direction) of the main body 21. The signal lead 30 includes, for example, an upper end, the surface of which is located on generally the same plane as the upper surface 21A of the main body 21, and a lower end, which projects downwardly from the lower surface of the main body 21.

The signal lead 30 is sealed by an encapsulant 35 inside the opening A1. The encapsulant 35 hermetically seals the opening A1 and fixes the signal lead 30 in the opening A1 (through hole 21X). Accordingly, the gap between the wall surface of the main body 21 that defines the opening A1 and the circumferential surface of the signal lead 30 is filled with the encapsulant 35, and the encapsulant 35 is adhered to the circumferential surface of the signal lead 30. Further, the encapsulant 35 contacts and covers the bottom surface of the projection B1. The encapsulant 35 functions to obtain an insulation distance between the signal lead 30 and the eyelet 20 and to fix the signal lead 30 in the through hole 21X. For example, glass or an insulative resin may be used as the material of the encapsulant 35. The glass may be, for example, a soft glass having a relative permittivity of approximately 6.7.

The opening A2 does not include the encapsulant 35. The opening A2 includes an air layer 36 that serves as a covering material. Accordingly, in the opening A2, the signal lead 30 is exposed to air, which has a relative permittivity of approximately 1. In other words, the opening A2 has a smaller relative permittivity than the encapsulant 35 and is filled with the air layer 36 (covering material) that covers the circumferential surface of the signal lead 30.

The encapsulant 35 (soft glass in present example) has a larger thermal expansion coefficient than the eyelet 20 (iron in present example). The difference in thermal expansion coefficient fastens the encapsulant 35 to the eyelet 20. Thus, the encapsulant 35 hermetically seals the opening A1. Further, the encapsulant 35 insulates the signal lead 30 from the eyelet 20 and fixes the signal lead 30 to the eyelet 20. As a result, the signal lead 30 and the encapsulant 35 define a coaxial line. That is, the portion sealed by the encapsulant 35 in the signal lead 30, which is inserted through the through hole 21X, functions as a coaxial line, the core of which is the signal lead 30.

In such a coaxial line, the characteristic impedance of the signal lead may be adjusted to a desired value by adjusting the diameters of the openings A1 and A2, the diameter of the signal lead 30, the relative permittivity of the encapsulant 35, and/or the relative permittivity of the covering material (relative permittivity of covering material is approximately 1 when covering material is air layer 36). In the present example, the diameters of the openings A1 and A2 are adjusted so that the characteristic impedance of the signal lead 30 has the desired value (e.g., 25Ω).

As illustrated in FIG. 1, the heat sink 22 projects from the upper surface 21A of the main body 21. The heat sink 22 has, for example, the form of a block and is generally semicircular in a plan view. The heat sink 22 includes a side surface that serves as a mounting surface 22A of the wiring substrate 40. The mounting surface 22A, which is generally orthogonal to the upper surface 21A of the main body 21, is a flat plane extending parallel to the XZ plane. Semiconductor elements are fixed to the wiring substrate 40, which is mounted on the mounting surface 22A.

As illustrated in FIG. 3, the mounting surface 22A bridges the two through holes 21X that are spaced apart by a given distance in the X-direction. The heat sink 22 is located at a position that is overlapped with portions of the openings A1 but not with the openings A2 in a plan view. In the present example, the mounting surface 22A of the heat sink 22 is located at a position spaced apart from the center of each of the openings A1 and A2 in a plan view by a distance that is shorter than the radius of the openings A1 and longer than or equal to the radius of the openings A2.

As illustrated in FIG. 4, the wiring substrate 40 mounted on the mounting surface 22A of the heat sink 22 includes a substrate 41 and conductive patterns 42 and 43 formed on the surface (front surface) of the substrate 41. The substrate 41 has the form of, for example, a flat plate. It is preferred that the substrate 41 be formed from a material having, for example, high thermal conductivity and superior electrical insulation properties. Such a material of the substrate 41 includes, for example, aluminum nitride (AlN) and alumina (Al₂O₃). The substrate 41 is, for example, slightly smaller than the mounting surface 22A in a plan view taken in the Y-direction. In the present example, the substrate 41 has a width (dimension in X-direction) that is smaller than that of the mounting surface 22A. Further, the substrate 41 has a height (dimension in Z-direction) that is smaller than that of the mounting surface 22A. The width of the substrate 41 may be, for example, approximately 2.4 to 2.8 mm. The height of the substrate 41 may be, for example, approximately 1.2 to 1.4 mm. Further, the thickness of the substrate 41 may be, for example, 0.2 to 0.3 mm.

The conductive patterns 42 and 43 are, for example, metalized patterns and spaced apart from each other. The conductive patterns 42 each correspond to one of the signal leads 30. Each conductive pattern 42 is connected to the corresponding signal lead 30 when the wiring substrate 40 is bonded to the mounting surface 22A of the heat sink 22. Further, each conductive pattern 42 is, for example, generally L-shaped as viewed in the Y-direction. Each conductive pattern 42 extends parallel to the axial direction (Z-direction) of the signal lead 30 from the lower end surface of the substrate 41 toward the upper portion of the substrate 41 where the conductive pattern 43 is located. Each conductive pattern 42 includes a bent portion 42A bent at an upper position (corner) of the substrate 41. The bent portion 42A includes a distal end located proximate to the conductive pattern 43. Accordingly, the bent portions 42A of the two conductive patterns 42 are opposed to each other at opposite sides of the conductive pattern 43. The bottom end surface of each conductive pattern 42 is exposed at the bottom end surface of the substrate 41. For example, as illustrated in FIG. 2B, the bottom end surface of each conductive pattern 42 is flush with the bottom end surface of the substrate 41. The conductive pattern 42 may have a width of, for example, approximately 0.2 to 0.3 mm and a thickness of, for example, 0.001 to 0.003 mm.

Referring to FIG. 4, the conductive pattern 43 is located between the two opposing bent portions 42A. In the present example, the conductive pattern 43 is rectangular as viewed in the Y-direction. The conductive pattern 43 serves as a semiconductor element mounting portion on which a semiconductor element is mounted. The conductive pattern 43 is electrically connected to the eyelet 20 by, for example, a conductor (not illustrated) extending through the substrate 41. Thus, when the eyelet 20 has the ground potential, the conductive pattern 43 also has the ground potential.

In the wiring substrate 40, the characteristic impedance of the conductive pattern 42 may easily be adjusted to the desired value. For example, the relative permittivity of the substrate 41, the thickness of the substrate 41, and/or the width and thickness of the conductive patterns 42 may be adjusted to adjust the characteristic impedance of the conductive pattern 42 to the desired value. In the wiring substrate 40, for example, the formation of a micro-strip line structure including a conductive layer having the ground potential on the rear surface of the substrate 41 allows the characteristic impedance of the conductive patterns 42 to be adjusted to the desired value.

The wiring substrate 40 is coupled to the eyelet 20 by bonding the rear surface of the substrate 41 to the mounting surface 22A. When the wiring substrate 40 is bonded to the mounting surface 22A, the front surface of the wiring substrate 40 where the conductive pattern 43 (mounting portion for semiconductor element) is formed is generally orthogonal to the upper surface 21A of the main body 21. The lower end surface of the substrate 41 is in contact with the upper surface 21A of the main body 21. In the present example, as illustrated in FIG. 3, the lower end surface of the substrate 41 is in contact with the upper surface 21A of the main body 21 at portions around the openings A2 and a portion between the openings A2. Accordingly, the wiring substrate 40 is arranged to bridge the two signal leads 30, which are spaced apart by a given distance in the X-direction. Further, the front surface of the wiring substrate 40 where the conductive patterns 42 are formed intersects the upper end surface of the each signal lead 30. As illustrated in FIGS. 2A and 2B, the lower end surface of each conductive pattern 42 is generally flush with the lower end surface of the substrate 41. Thus, the lower end surface of each conductive pattern 42 is in contact with the upper end surface of each signal lead 30, which is generally flush with the upper surface 21A of the main body 21. This electrically connects the conductive patterns 42 to the signal leads 30.

In the header 10 of the present example, the rear surface of the substrate 41 is brazed and bonded to the mounting surface 22A, and the lower end surface of the substrate 41 is brazed and bonded to the upper surface 21A of the main body 21. Further, in the header of the present example, the conductive patterns 42 are brazed and bonded to the signal leads 30. This ensures that the conductive patterns 42 are electrically connected to the signal leads 30. In this manner, the wiring substrate 40 is coupled to the eyelet 20 with the conductive patterns 42 electrically connected to the signal leads 30.

The bonding and electrical connection of the conductive patterns 42 and the signal leads 30 do not have to be achieved through brazing. A conductive adhesive may be used instead of performing brazing. When bonding the conductive patterns 42 and the signal leads 30, short-circuiting of the conductive patterns 42 and the signal leads 30 needs to be avoided.

As illustrated in FIG. 1, the main body 21 includes a through hole 21Y at a given location (single location). The through hole 21Y extends through the main body 21 in the thickness-wise direction. In the present example, the through hole 21Y does not include a step. Nevertheless, in the same manner as the openings A1 and A2 in the through holes 21X, the through hole 21Y may include a step.

The monitor lead 31 is inserted through the through hole 21Y. Accordingly, the axial direction of the monitor lead 31 coincides with the thickness-wise direction of the main body 21 (Z-direction). The monitor lead 31 is sealed by an encapsulant 37 in the through hole 21Y. That is, the encapsulant 37 hermetically seals the through hole 21Y and fixes the monitor lead 31 in the through hole 21Y. The monitor lead 31 is, for example, cylindrical. In the present example, the monitor lead 31 includes an upper portion that projects upwardly from the upper surface 21A of the main body 21 and a lower portion that projects downwardly from the lower surface of the main body 21. The encapsulant 37 may be formed from the same material as the encapsulant 35 (refer to FIG. 2A).

As illustrated in FIG. 2A, the ground lead 32 extends downwardly from the lower surface of the main body 21. The ground lead 32 is, for example, bonded to the lower surface of the main body 21 through bonding or the like. Thus, when the ground lead 32 is connected to ground, the eyelet 20 (main body 21 and heat sink 22) is also connected to ground. In this case, the heat sink 22 also functions as a grounding portion set at the ground potential. The ground lead 32 is, for example, cylindrical. The axial direction of the ground lead 32 coincides with the Z-direction.

The header 10 may be manufactured, for example, through the method described below. The main body 21 and the heat sink 22 of the eyelet 20 may be formed integrally through stamping such as cold forging or the like. The heat sink 22 is located at a position that does not overlap the openings A2 in a plan view. This allows both of the main body 21, which includes the through holes 21X (openings A1 and A2), and the heat sink 22 to be formed through stamping.

Then, for example, when the encapsulant 35 is formed from glass, a known powder pressing process or extrusion molding process is performed to mold glass powder into a tubular molded product having the form of the encapsulant 35. The tubular molded product has an inner diameter (hole diameter) that coincides with the diameter of the signal lead 30 and an outer diameter that coincides with the diameter of the opening A1. The tubular molded product is fitted into the opening A1, and the signal lead 30 is inserted through the hole of the tubular molded product. The encapsulant 35 (tubular molded product) is heated to a given temperature and melted. Then, the encapsulant 35 is cooled and solidified. As a result, the signal lead 30 is sealed by the encapsulant 35 and fixed in the opening A1 with the signal lead 30 insulated from the eyelet 20. In this step, as heat melts glass into a certain form (form of encapsulant 35), the glass always becomes spherical and then forms a free surface that becomes a curved surface and not a horizontal surface. Thus, as illustrated in FIG. 2B, the end surface (upper end surface in present example) of the encapsulant 35 produces a gap S1 in the opening A1. The upper end surface of the encapsulant 35 is partially pressed by the bottom surface of the projection B1. Thus, only a portion of the upper end surface of the encapsulant 35 forms the free surface. This reduces the free surface of the encapsulant 35 in size and reduces the volume of the gap S1, which is filled with air having a relative permittivity of approximately 1, as compared with when forming the encapsulant 135 in the through hole 121X that is less a step (projection B1) like in the semiconductor device 100 of FIG. 8. For example, when the opening A1 is set to have the same diameter as the through hole 121X of FIG. 8, the volume of the gap S1 produced by the encapsulant 35 in the through hole 121X would be smaller than the volume of the gap S2 formed in the through hole 121X by the encapsulant 135. This minimizes variations in the characteristic impedance of the signal lead 30 caused by the gap S1. Further, differences in the characteristic impedance may be minimized at the portion connecting the signal lead 30 and the conductive pattern 42.

The conductive patterns 42 of the wiring substrate 40 are then positioned on the signal leads 30, and brazing or the like is performed to bond the wiring substrate 40 to the mounting surface 22A of the heat sink 22 and the upper surface 21A of the main body 21. The bonding or the like simultaneously connects the signal leads 30 to the conductive patterns 42. The signal leads 30 may be connected to the conductive patterns 42 after bonding the wiring substrate 40 to the eyelet 20.

The method described above allows the semiconductor device header 10 to be manufactured.

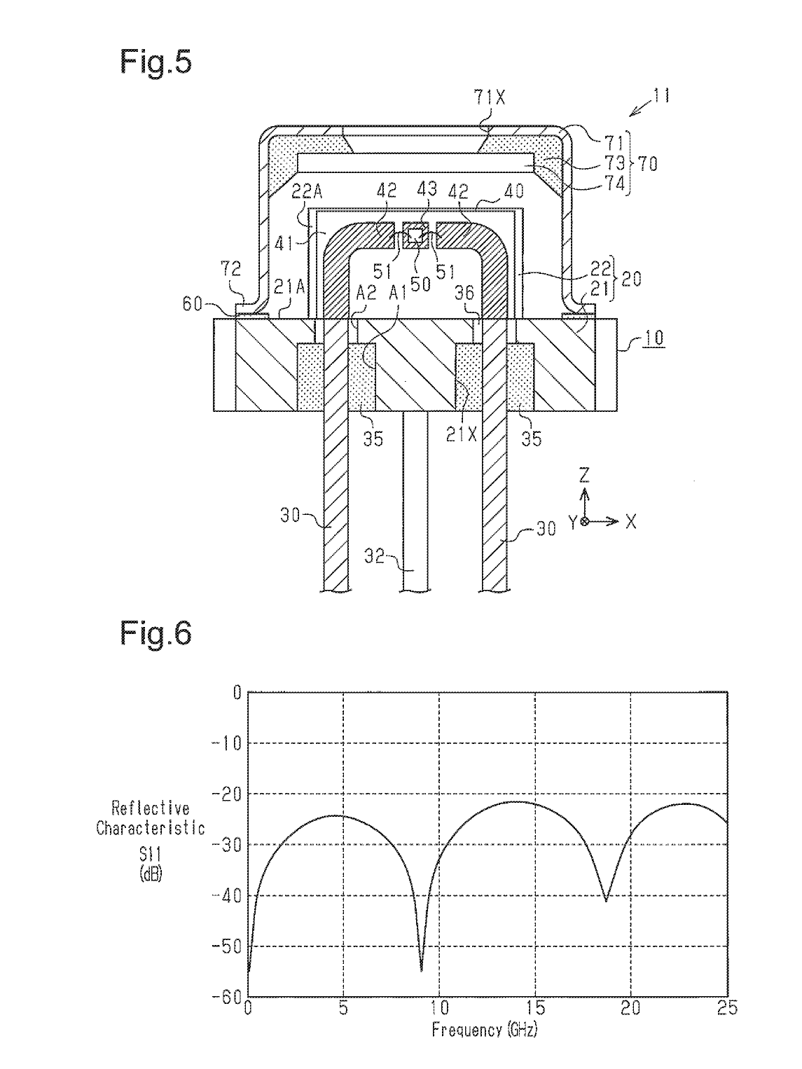

The structure of a semiconductor device 11 in which a semiconductor element 50 is mounted on the header 10 will now be described with reference to FIG. 5.

The semiconductor device 11 includes the header 10, the semiconductor element 50, a bond 60, and a cap 70. The semiconductor element 50 may be, for example, a light emitting element. A semiconductor laser chip having a wavelength of 1310 nm, for example, may be used as the light emitting element.

The semiconductor element 50 is fixed to the surface of the conductive pattern 43 on the wiring substrate 40 with, for example, the light emitting surface (here, upper end surface) directed toward the upper side. In this case, the semiconductor element 50 is mounted on the header 10 so that the light emitting point of the semiconductor element 50 is generally aligned with the center of the upper surface 21A of the main body 21 in a plan view. The electrodes (not illustrated) of the semiconductor element 50 are electrically connected to the conductive patterns 42 by, for example, bonding wires 51. This electrically connects the signal leads 30 to the semiconductor element 50 with the conductive patterns 42. Further, the rear surface of the semiconductor element 50 includes, for example, a ground electrode (not illustrated). When the semiconductor element 50 is mounted on the conductive pattern 43, the ground electrode and the conductive pattern 43 are electrically connected.

The bond 60 is formed on the upper surface 21A of the main body 21 surrounding the heat sink 22, the signal leads 30, and the monitor lead 31 (refer to FIG. 1). The bond 60 is, for example, generally annular. The bond 60 may be a metal layer obtained by sequentially laminating a nickel (Ni) layer and a gold (Au) layer, which have superior anti-corrosion properties.

The cap 70 has the form of a hollow hat. The cap 70 includes a cylindrical cap body 71, which is provided with a top plate. The top plate includes an opening 71X (window) extending through the central part in a plan view. The cap 70 further includes a transparent member 74 located below the opening 71X. The transparent member 74 is adhered to the cap body 71 by an adhesive 73. A gap between the top plate of the cap body 71 and the portion around the transparent member 74 is filled with the adhesive 73 to seal the opening 71X of the cap 70 from the external environment. The cap 70 includes a flange 72, which is annular (ring-shaped in present example) and formed by bending the bottom circumference of the cap body 71 toward the outer side. The lower surface of the flange 72 is bonded to the bond 60. This bonds the cap 70 to the eyelet 20 and hermetically seals the inside of the cap 70, which accommodates the semiconductor element 50 fixed to the wiring substrate 40. The cap 70 may be bonded to the bond 60 through, for example, electric resistance welding.

The cap body 71 may be formed from, for example, a metal such as iron or copper or an alloy including at least one of these metals. The adhesive 73 may be formed from, for example, a low-melting-point glass. The transparent member 74 may be formed from, for example, glass. The opening 71X, the adhesive 73, and the transparent member 74 may be omitted from the cap 70. Further, the bond 60 may be omitted, and the cap 70 may be directly bonded to the upper surface 21A of the main body 21 through welding or the like.

In the semiconductor device 11 described above, the light emitted from the light emitting surface (upper end surface in present example) of the semiconductor element 50 is transmitted through the transparent member 74 and out of the opening 71X in the Z-direction (here, upper direction).

The operation of the semiconductor device 11 will now be described.

In the semiconductor device 11, the signal leads 30 sealed by the encapsulant 35 in the through holes 21X are electrically connected to the conductive patterns 42 of the wiring substrate 40, and the conductive patterns 42 are electrically connected to the semiconductor element 50 by the bonding wires 51. Thus, the conductive patterns 42 electrically connect the upper ends of the signal leads 30 to the semiconductor element 50. The lower ends of the signal leads 30 are electrically connected to, for example, an external electric circuit (not illustrated). As a result, the signal leads 30 function to transmit input-output signals having a high frequency between the semiconductor element 50 and the external electric circuit. Here, the portion of the signal lead 30 sealed by the encapsulant 35 in the corresponding through hole 21X serves as a coaxial line (coaxial structure). Thus, the characteristic impedance of the signal lead 30 can easily be adjusted by adjusting the diameter of the signal lead 30, the diameters of the openings A1 and A2, the relative permittivity of the encapsulant 35, and/or, the relative permittivity of the covering material (air layer 36 in present example). For example, the diameters of the openings A1 and A2 are adjusted in a suitable manner to match the characteristic impedance of the signal leads 30 with a desired characteristic impedance value (e.g., characteristic impedance of circuits included in semiconductor element 50) such as 25Ω. Further, the characteristic impedance of the conductive patterns 42 electrically connecting the signal leads 30 and the semiconductor element 50 may also be easily adjusted to a desired value as described above. This allows the characteristic impedance value to be matched in the entire transmission line of the semiconductor device 11. As a result, the reflection loss of high-frequency signals may be decreased, and the transmission characteristics of high-frequency signals may be maintained in a satisfactory manner.

For example, when the relative permittivity of the encapsulant 35 is 6.7 and the diameter of the signal lead 30 is 0.32 mm, the diameter of the opening A1 may be set to 0.93 mm so that the characteristic impedance of the signal lead 30 in the opening A1 is matched to 25Ω. When the relative permittivity of the air layer 36 is 1 and the diameter of the signal lead 30 is 0.32 mm, the diameter of the opening A2 may be set to 0.48 mm in order to match the characteristic impedance of the signal lead 30 in the opening A2 to 25Ω. The relative permittivity of the air layer 36 is smaller than the relative permittivity of the encapsulant 35. Thus, the diameter of the opening A2 may be set to be smaller than the diameter of the opening A1. Further, the wiring substrate 40 may be set so that the substrate 41, which is formed from aluminum nitride having a relative permittivity of 8.7, has a thickness of 0.3 mm and the conductive pattern 42 has a width of 0.3 mm and a thickness of 0.002 mm in order for the characteristic impedance of the conductive pattern 42 to be matched at 25Ω.

Further, in the semiconductor device 11, the distance from the center of each of the openings A1 and A2 to the mounting surface 22A in a plan view is set to be shorter than the radius of the opening A1 (0.465 mm) and longer than or equal to the radius of the opening A2 (0.24 mm). For example, when the distance is set to 0.3 mm, the heat sink 22 overhangs the opening A1 having the diameter of 0.93 mm by 0.165 mm, and the heat sink 22 is separated by 0.06 mm from the open end of the opening A2 having the diameter of 0.48 mm. In this manner, the heat sink 22 may be located proximate to the center of each of the openings A1 and A2 within a range in which the heat sink 22 does not overhang the opening A2. Thus, the lower end surfaces of the conductive patterns 42 formed on the front surface of the substrate 41 may be connected in a suitable manner to the upper end surfaces of the signal leads 30 without increasing the thickness of the substrate 41. Since the heat sink 22 does not overhang the opening A2, the heat sink 22 may be stamped and formed together with the main body 21, which includes the through holes 21X and 21Y.

FIG. 6 illustrates characteristic changes caused by impedance mismatching when connecting the header 10 to an impedance port having 25Ω in order to check the transmission characteristics of the high-frequency signals of the semiconductor device header 10. More specifically, FIG. 6 illustrates the frequency characteristics of a reflection signal of an input signal.

As apparent from the simulation results of FIG. 6, the semiconductor device header 10 reduces the reflection loss of the input signal. Even when the frequency of the input signal is 20 GHz or higher, the reflective characteristics S11 is maintained at a small value of −20 dB or lower. From this result, it is understood that the transmission characteristics of high-frequency signals are maintained at a satisfactory level.

The above embodiment has the advantages described below.

(1) The eyelet 20 (base) of the semiconductor device header 10 includes the main body 21 and the heat sink 22. The signal leads 30 are inserted through the through holes 21X in the thickness-wise direction of the main body 21. Each through hole 21X is defined by the opening A1 and the opening A2, which opens in the upper surface 21A of the main body 21 and is smaller than the opening A1 in a plan view. The heat sink 22, which includes the mounting surface 22A, is located at a position partially overlapped with the opening A1 in a plan view and separated from the opening A2 in a plan view. This allows the main body 21, which includes the through hole 21X, to be stamped and formed together with the heat sink 22. Accordingly, the manufacturing cost of the semiconductor device header 10 may be decreased.

(2) The center of each of the openings A1 and A2 may be located proximate to the mounting surface 22A within a range in which the heat sink 22 does not overhang the opening A2. This connects the lower end surfaces of the conductive patterns 42 to the upper end surfaces of the signal leads 30 in a suitable manner without increasing the thickness of the substrate 41. Further, there is no need to arrange a separate member such as a spacer between the wiring substrate 40 and the mounting surface 22A. This reduces the number of components as compared with the semiconductor device 100 of FIG. 8 and decreases the manufacturing cost of the semiconductor device header 10. Moreover, the wiring substrate 40 may be directly bonded to the mounting surface 22A. This improves the mounting accuracy of the wiring substrate 40.

(3) The upper end surface of the encapsulant 35 is in contact with the bottom surface of the projection B1. This decreases the volume of the gap S1 produced by the encapsulant in the opening A1. Variations in the characteristic impedance of the signal lead 30 caused by the gap S1 can be reduced, and differences in the characteristic impedance of the portion connecting the signal lead 30 and the conductive patterns 42 can be reduced.

(4) The characteristic impedance can be matched in the entire transmission line of the semiconductor device 11. As a result, the reflection loss of high-frequency signals may be decreased, and the transmission characteristics of high-frequency signals may be maintained in a satisfactory manner.

It should be apparent to those skilled in the art that the foregoing embodiments may be employed in many other specific forms without departing from the spirit or scope of this disclosure. Particularly, it should be understood that the foregoing embodiments may be employed in the following forms.

In the above embodiment, the single semiconductor element 50 is mounted on the header 10 that includes the two through holes 21X. Instead, a plurality of semiconductor elements may be mounted on the header 10, and the number of the through holes 21X and the number of signal leads 30 may be changed in accordance with the number of the mounted semiconductor elements and the number of terminals of the semiconductor elements.

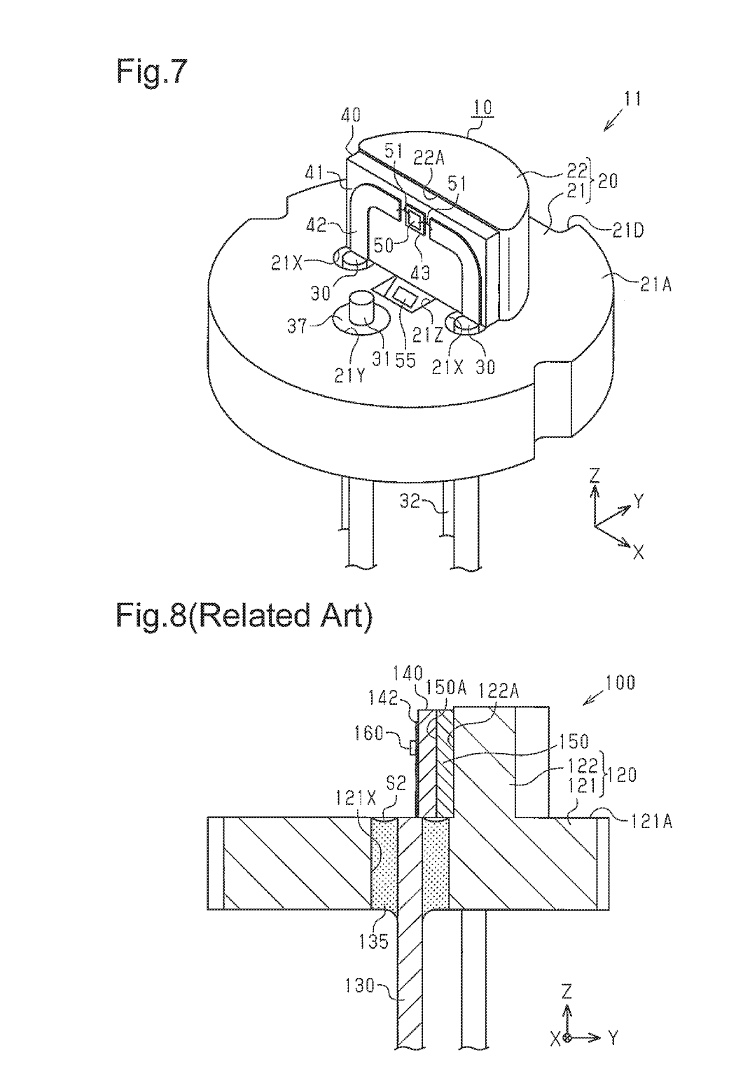

For example, as illustrated in FIG. 7, two semiconductor elements 50 and 55 may be mounted on the step 10. For example, a light emitting element may be used as the semiconductor element 50, and a light receiving element may be used as the semiconductor element 55. The light receiving element may be, for example, a photodiode. The upper surface 21A of the main body 21 includes a recess 21Z that receives the semiconductor element 55. In the present example, the recess 21Z is located between the two through holes 21X in a plan view proximate to the conductive pattern 43 (mounting portion of semiconductor element 50). The recess 21Z includes a bottom surface formed as, for example, an inclined surface that is downwardly inclined from the front side of the wiring substrate 40 toward the rim of the main body 21. The semiconductor element 55 is mounted on the inclined surface (bottom surface) of the recess 21Z. The electrodes (not illustrated) of the semiconductor element 55 are electrically connected to the signal leads 30 by conductive patterns or the like formed on the wiring substrate 40 or by bonding wires.

In the semiconductor device illustrated in FIG. 7, light is emitted from the upper end surface of the semiconductor element 50 (light emitting element) in the Z-direction (here, upper direction). Further, light is emitted from the lower end surface of the semiconductor element 50 and received by the semiconductor element 55 (light receiving element). For example, the semiconductor element 55 monitors the emitted light amount of the semiconductor element 50 and controls the emitted light amount to be constant at the semiconductor element 55 with a circuit located outside the semiconductor device 11. This keeps the emitted light amount constant regardless of the ambient temperature.

In the above embodiment, the opening A2 includes the air layer 36. Instead, the opening A2 may be filled with a covering material formed from a material having a smaller relative permittivity than the encapsulant 35 (material other than air).

The shapes of the conductive patterns 42 and 43 in the above embodiment are not limited in particular.

The conductive pattern 43 may be omitted in the above embodiment.

A resin substrate such as a glass epoxy substrate may be used as the substrate 41 in the above embodiment.

In the above embodiment, the upper end surface of the signal lead 30 is located on generally the same plane as the upper surface 21A of the main body 21. However, the location of the upper end surface of the signal lead 30 is not limited in particular as long as the signal lead 30 can be electrically connected to the conductive pattern 42. For example, the upper end surface of the signal lead 30 may be projected upwardly from the upper surface 21A of the main body 21.

In the above embodiment, the signal lead 30 is generally cylindrical. Instead, for example, the signal lead 30 may have the form of a polygonal post, such as a triangular post or a quadrangular post, or the form of an elliptic post.

In the above embodiment, the openings A1 and A2 are generally cylindrical. Instead, for example, the openings A1 and A2 may have the form of a polygonal post, such as a triangular post or a quadrangular post, or the form of an elliptic post. In this case, it is preferred that the openings A1 and A2 be shaped similar to the signal lead 30.

The through hole 21Y, the monitor lead 31, and the encapsulant 37 may be omitted from the above embodiment.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to an illustration of the superiority and inferiority of the invention. Although embodiments have been described in detail, it should be understood that various changes, substitutions, and alterations could be made hereto without departing from the spirit and scope of the invention.

1. A semiconductor device header comprising:
a base including a main body and a heat sink projecting from an upper surface of the main body and formed integrally with the main body;
a through hole that extends through the main body in a thickness-wise direction, wherein the through hole is defined by a first opening and a second opening, the second opening opens in the upper surface of the main body, and the second opening is in communication with the first opening and is smaller than the first opening in a plan view;
a lead inserted through the through hole;
an encapsulant with which the first opening is filled to seal the lead;
a covering material with which the second opening is filled, wherein the covering material has a smaller relative permittivity than the encapsulant; and
a wiring substrate bonded to a mounting surface of the heat sink, wherein the wiring substrate includes a conductive pattern, electrically connected to the lead, and a mounting portion, on which a semiconductor element is mounted,
wherein the heat sink is located at a position partially overlapped with the first opening in a plan view and separated from the second opening in a plan view.

2. The semiconductor device header according to claim 1, wherein
the main body includes a projection located above the first opening and projected into the through hole from an upper outer rim of the first opening to define the second opening, and
the encapsulant in the first opening is in contact with a bottom surface of the projection.

3. The semiconductor device header according to claim 1, wherein the covering material comprising an air layer.

4. The semiconductor device header according to claim 1, wherein
the first opening has a diameter and the second opening has a diameter; and
the diameters of the first and second openings are set so that the lead has a desired characteristic impedance value.

5. A semiconductor device comprising:
the semiconductor device header according to claim 1;
a semiconductor element mounted on the mounting portion of the wiring substrate and electrically connected to the conductive pattern; and
a cap bonded to the main body of the header.
